(19) United States
(12) Patent Application Publication
(10) Pub. No.: US 2025/0359392 A1
(43) Pub. Date: Nov. 20, 2025

(54) LIGHT DETECTION SENSOR

(71) Applicant: SAMSUNG ELECTRONICS CO., LTD., Suwon-si (KR)

(72) Inventors: Jaesang Yoo, Suwon-si (KR); Seungjoon Lee, Suwon-si (KR); Minwook Jung, Suwon-si (KR); Jeongki Kim, Suwon-si (KR); Chungho Song, Suwon-si (KR)

(73) Assignee: SAMSUNG ELECTRONICS CO., LTD., Suwon-si (KR)

(21) Appl. No.: 19/008,135

(22) Filed: Jan. 2, 2025

(30) Foreign Application Priority Data
May 20, 2024 (KR) 10-2024-0065227

(51) Int. Cl. H10F 77/20; H10F 39/00

(52) U.S. Cl. CPC H10F 77/244; H10F 39/807; H10F 39/812

(57) ABSTRACT

Provided is a light detection sensor including: a substrate including a first surface and a second surface opposite to the first surface, wherein the second surface is a light incident surface; a deep trench isolator within a deep trench in the substrate and defining a pixel area; at least one recess into the pixel area from the second surface; a transparent electrode on the second surface and an inner surface of the at least one recess; and a first insulating film between the transparent electrode and the second surface and between the transparent electrode and the inner surface of the at least one recess.

### CROSS-REFERENCE TO RELATED APPLICATION

This application is based on and claims benefit of priority to Korean Patent Application No. 10-2024-0065227, filed on May 20, 2024, in the Korean Intellectual Property Office, the disclosure of which is incorporated herein by reference in its entirety.

### BACKGROUND

### 1. Field

The present disclosure relates to a light detection sensor.

### 2. Description of Related Art

A light detection sensor may be a semiconductor device that can convert optical signals into electrical signals. The light detection sensor may include a photodiode (PD) as a photoelectric conversion element. Typically, a photodiode may be formed within a semiconductor substrate and may convert incident light into electrical signals. When the light is incident on the photodiode, part of the light may be lost due to reflection and/or absorption. In addition, the semiconductor substrate may be damaged by manufacturing processes, or the like, thereby causing dark current in the photodiode. Various studies are being conducted to minimize these phenomena (i.e., light loss and dark current).

### SUMMARY

Provided is a light detection sensor that can improve photoelectric conversion efficiency.

Further provided is a light detection sensor that can minimize dark current.

According to an aspect of the disclosure, a light detection sensor includes: a substrate including a first surface and a second surface opposite to the first surface, wherein the second surface is a light incident surface; a deep trench isolator within a deep trench in the substrate and defining a pixel area; at least one recess into the pixel area from the second surface; a transparent electrode on the second surface and an inner surface of the at least one recess; and a first insulating film between the transparent electrode and the second surface and between the transparent electrode and the inner surface of the at least one recess.

According to an aspect of the disclosure, a light detection sensor includes: a substrate including a first surface and a second surface opposite to the first surface, wherein the second surface is a light incident surface; a deep trench isolator within a deep trench in the substrate and defining a plurality of pixel areas; at least one recess in each of the plurality of pixel areas from the second surface; a transparent electrode on the second surface and inner surfaces of each of the at least one recess in each of the plurality of pixel areas; a first insulating film between the transparent electrode and the second surface and between the transparent electrode and the inner surfaces of each of the at least one recess in each of the plurality of pixel areas; and a second insulating film on each transparent electrode.

### BRIEF DESCRIPTION OF DRAWINGS

The above and other aspects and features of certain embodiments of the present disclosure will be more apparent from the following description taken in conjunction with the accompanying drawings, in which:

FIG. 1 is a cross-sectional view of a light detection sensor according to one or more embodiments of the present disclosure;

FIGS. 2A, 2B and 2C are cross-sectional views of light detection sensors according to one or more embodiments of the present disclosure;

FIGS. 3A and 3B are cross-sectional views of light detection sensors according to one or more embodiments of the present disclosure;

FIG. 4 is a cross-sectional view of a light detection sensor according to one or more embodiments of the present disclosure;

FIGS. 5A and 5B are cross-sectional views of light detection sensors according to one or more embodiments of the present disclosure;

FIG. 6A is a cross-sectional view of a light detection sensor according to one or more embodiments of the present disclosure;

FIGS. 6B and 6C are plan views showing light detection sensors according to one or more embodiments of the present disclosure;

FIGS. 7A, 7B, 7C and 7D are cross-sectional views sequentially showing a manufacturing method of a light detection sensor according to one or more embodiments of the present disclosure;

FIGS. 8A, 8B, 8C, 8D, 8E and 8F are cross-sectional views sequentially showing a manufacturing method of a light detection sensor according to one or more embodiments of the present disclosure;

FIGS. 9A, 9B and 9C are cross-sectional views sequentially showing a manufacturing method of a light detection sensor according to one or more embodiments of the present disclosure;

FIG. 10 is a circuit diagram of pixels of a light detection sensor according to one or more embodiments of the present disclosure;

FIG. 11 is a cross-sectional view showing a light detection sensor according to one or more embodiments of the present disclosure;

FIG. 12 is a cross-sectional view showing a light detection sensor according to one or more embodiments of the present disclosure;

FIG. 13 is a cross-sectional view showing a light detection sensor according to one or more embodiments of the present disclosure; and

FIG. 14 is a cross-sectional view showing a light detection sensor according to one or more embodiments of the present disclosure.

### DETAILED DESCRIPTION

Hereinafter, embodiments of the present disclosure will be described in more detail with reference to the accompanying drawings.

In the following description, like reference numerals refer to like elements throughout the specification. As used herein, a plurality of “units”, “modules”, “members”, and “blocks” may be implemented as a single component, or a single “unit”, “module”, “member”, and “block” may include a plurality of components.

It will be understood that when an element is referred to as being “connected” with or to another element, it can be directly or indirectly connected to the other element.

Also, when a part “includes” or “comprises” an element, unless there is a particular description contrary thereto, the part may further include other elements, not excluding the other elements.

Throughout the description, when a member is “on” another member, this includes not only when the member is in contact with the other member, but also when there is another member between the two members.

As used herein, the expressions “at least one of a, b or c” and “at least one of a, b and c” indicate “only a,” “only b,” “only c,” “both a and b,” “both a and c,” “both b and c,” and “all of a, b, and c.”

It will be understood that, although the terms “first”, “second”, “third”, etc., may be used herein to describe various elements, is the disclosure should not be limited by these terms. These terms are only used to distinguish one element from another element.

As used herein, the singular forms “a,” “an” and “the” are intended to include the plural forms as well, unless the context clearly indicates otherwise.

With regard to any method or process described herein, an identification code may be used for the convenience of the description but is not intended to illustrate the order of each step or operation. Each step or operation may be implemented in an order different from the illustrated order unless the context clearly indicates otherwise. One or more steps or operations may be omitted unless the context of the disclosure clearly indicates otherwise.

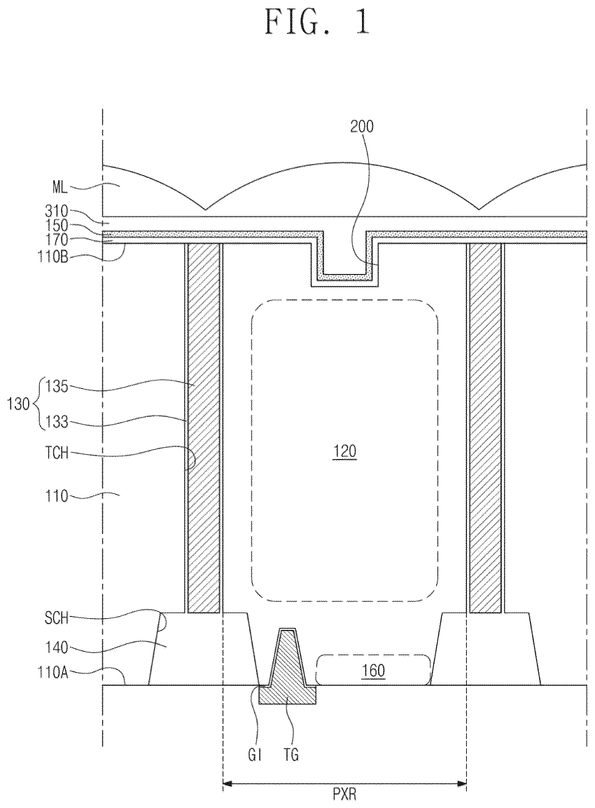

FIG. 1 is a cross-sectional view of a light detection sensor according to one or more embodiments of the present disclosure.

Referring to FIG. 1, the light detection sensor according to one or more embodiments of the present disclosure may include a substrate 110, a deep trench isolator 130, a shallow trench isolator 140, a recess 200, a transparent electrode 150, a first insulating film 170, a second insulating film 310, and a microlens ML.

The substrate 110 may have a first surface 110a and a second surface 110b that face in opposite directions. The first surface 110a of the substrate 110 may be a front surface, and the second surface 110b of the substrate 110 may be a back surface. Light may be incident on the second surface 110b of the substrate 110. Accordingly, the second surface 110b may be a light incident surface.

The substrate 110 may be a semiconductor substrate or an SOI (Silicon on Insulator) substrate. The substrate 110 may include, for example, a silicon substrate, a germanium substrate, or a silicon-germanium substrate. The substrate 110 may include impurities of a first conductivity type. Accordingly, the substrate 110 may have the first conductivity type. The impurities of the first conductivity type may be a group 13 element. For example, the impurities of the first conductivity type may be p-type impurities such as boron (B).

The deep trench isolator 130 may be formed in the substrate 110 to define a pixel area PXR. The pixel area PXR may be a portion of the substrate 110 surrounded by the deep trench isolator 130. In FIG. 1, one pixel area PXR is illustrated, but embodiments of the present disclosure are not limited thereto. In one or more embodiments, the deep trench isolator 130 may define the plurality of pixel areas PXR in the substrate 110, and the plurality of pixel areas PXR may be arranged in a two-dimensional matrix form.

A photoelectric conversion area 120 may be provided in the pixel area PXR. The photoelectric conversion area 120 may be interposed between the first surface 110a and the second surface 110b of the substrate 110. In one or more embodiments, the photoelectric conversion area 120 may be spaced apart from the first surface 110a and the second surface 110b of the substrate 110. The photoelectric conversion area 120 may be a doped area including impurities of a second conductivity type. The second conductivity type may be a conductivity type opposite to the first conductivity type. In one or more embodiments, impurities of the second conductivity type may include a group 5 element. For example, the impurities of the second conductivity type may include n-type impurities such as phosphorus and/or arsenic. The photoelectric conversion area 120 having the second conductivity type may configure a photoelectric conversion element (e.g., a photodiode) by being PN-junctioned with the pixel area PXR having the first conductivity type

The deep trench isolator 130 may be provided within a deep trench (TCH) formed on the substrate 110. In this case, the deep trench TCH may be in contact with the first surface 110a and the second surface 110b. In one or more embodiments, the deep trench isolator 130 may pass through the second surface 110b of the substrate 110. The deep trench isolator 130 may be recessed from the first surface 110a or the second surface 110b of the substrate 110. In one or more embodiments, the deep trench isolator 130 may pass through the substrate 110.

In one or more embodiments, the deep trench isolator 130 may include an insulating liner 133 and a buried conductive pattern 135. However, the embodiments of the present disclosure are not limited thereto. In one or more embodiments, the deep trench isolator 130 may include other components.

The insulating liner 133 may be provided along an inner side surface of the deep trench (TCH). The insulating liner may conformally cover the inner side surface of the deep trench (TCH). The insulating liner 133 may be provided between the substrate 110 and the buried conductive pattern 135 to electrically insulate the substrate 110 and the buried conductive pattern 135 from each other.

The insulating liner 133 may include an insulating material, such as a silicon-based insulating material (e.g., a silicon nitride (Si₃N₄), a silicon oxide (SiO₂), a silicon oxynitride, and/or a silicon carbon nitride (SiCN)) and/or a high dielectric metal oxide (e.g., a hafnium oxide (HfOx), a zirconium oxide (ZrO₂), and/or an aluminum oxide (Al₂O₃), etc.).

The insulating liner 133 is shown as a single layer in FIG. 1, but is not limited thereto. In one or more embodiments, the insulating liner 133 may include a plurality of stacked layers, and the stacked layers may include different materials from each other.

The insulating liner 133 may have a smaller refractive index than the substrate 110. Accordingly, crosstalk between pixels may be reduced or minimized.

The buried conductive pattern 135 may be formed of a conductive material (e.g., doped poly-silicon or a metal). The doped poly-silicon may include the impurities of the first conductivity type (e.g., P-type) or the impurities of the second conductivity type (e.g., N-type). For example, the buried conductive pattern 135 may include poly-silicon doped with boron (B), or poly-silicon doped with phosphorus (P) or arsenic (As).

When the buried conductive pattern 135 includes a metal, the buried conductive pattern 135 may include copper, tungsten, aluminum, and/or titanium. However, the embodiments of the present disclosure are not limited thereto. In one or more embodiments, the buried conductive pattern 135 may include other conductive material, for example, at least one of various other metals, an organic/inorganic material doped with an impurity, or a combination thereof. For example, the other conductive material may include a conductive metal oxide, a metal grid, a random metal network, a carbon nanotube, a graphene, a nanowire mesh, an ultra-thin metal film, and/or a conductive polymer.

In one or more embodiments of the present disclosure, the conductive metal oxide may be an indium tin oxide (ITO), an indium zinc oxide (IZO), an aluminum-doped zinc oxide (ZnO:Al; AZO), and an indium gallium zinc oxide (indium gallium zinc oxide (IGZO)), a fluorine-doped tin oxide, and/or a niobium-doped anatase.

According to one or more embodiments, the buried conductive pattern 135 may be omitted. In this case, the deep trench isolator 130 may include an insulating pattern provided on the insulating liner 133 to fill the deep trench (TCH).

A shallow trench isolator 140 may be formed in the substrate 110 to define an active area. The shallow trench isolator 140 may fill a shallow trench SCH recessed into the substrate 110 from the first surface 110a of the substrate 110. Accordingly, the shallow trench isolator 140 may be disposed adjacent to the first surface 110a of the substrate 110. The shallow trench isolator 140 may be exposed by the first surface 110a. The active area may be defined within the pixel area (PXR). The active area may be a portion of the substrate 110 surrounded by the shallow trench isolator 140.

A shallow trench (SCH) may be connected to the deep trench (TCH). Accordingly, a portion of the shallow trench isolator 140 may vertically overlap the deep trench isolator 130. The shallow trench isolator 140 may be connected to the deep trench isolator 130.

The shallow trench isolator 140 may include at least one of various insulating materials. For example, the shallow trench isolator 140 may include at least one of a silicon oxide film, a silicon nitride film, or a silicon oxynitride film.

A transfer gate TG may be disposed on the first surface 110a of the substrate 110 and may vertically overlap the active area. For example, the transfer gate TG extends into the substrate 110. A gate dielectric film (GI) may be disposed between the transfer gate (TG) and the active area. In one or more embodiments, the transfer gate TG may fill a gate trench recessed from the first surface 110a into the active area. In this case, the gate dielectric film GI may be extended to be also disposed between the transfer gate TG and an inner surface of the gate trench. When the transfer gate (TG) fills the gate trench, a transistor including the transfer gate (TG) may be a vertical channel type transistor.

A floating diffusion region 160 may be provided within the active area of one side of the transfer gate TG. The floating diffusion region 160 may be a region doped with impurities. The floating diffusion region 160 may include impurities of the second conductivity type. When light is incident into the photoelectric conversion area 120, photocharges may be generated and accumulated within the photoelectric conversion area 120. When the transistor including the transfer gate (TG) is turned on, the accumulated photocharges may be transferred to the floating diffusion region 160 through the transistor.

The recess 200 may be recessed from the second surface 110b of the substrate 110 into the pixel area PXR. In the embodiment of FIG. 1, one recess 200 may be provided in the pixel area PXR. However, the embodiments of the present disclosure are not limited thereto. In one or more embodiments, a plurality of recesses 200 may be provided within the pixel area PXR.

According to the embodiment of FIG. 1, a cross-section of the recess 200 may have a substantially rectangular shape, but is not limited thereto. In one or more embodiments, the cross-section of recess 200 may have one of a variety of other shapes. Examples related to this will be described below.

From a plan view, the shape of the recess 200 may be modified in various ways. For example, a planar shape of the recess 200 may be a circular shape, an elliptical shape, a rectangular shape, a polygonal shape, a cross shape, or a bar shape, but is not limited thereto.

The transparent electrode 150 may be provided on the second surface 110b of the substrate 110 and an inner surface of the recess 200. In other words, the transparent electrode 150 may cover the second surface 110b and the inner surface of the recess 200.

The transparent electrode 150 may include a transparent conductive material. Specifically, the transparent electrode 150 may have a transmittance of about 70% or more. For example, the transparent electrode 150 may include a material with a transmittance of 80% or more and may have high electrical conductivity and low resistance at the same time. For example, the electrical conductivity may be 10³ S/cm or more, and the low resistance may be 10⁻³ Ωcm or less. Here, the transparent conductive material may have a bandgap larger than that of visible light so that visible light passes through without being absorbed. For example, the transparent conductive material may have a bandgap of 3.5 eV (400 nm) or more.

For example, the transparent conductive material may include a transparent conductive oxide. For example, the transparent conductive oxide may include at least one of an indium tin oxide (ITO), an indium zinc oxide (IZO), an indium gallium zinc oxide (IGZO), a titanium oxide (TiO2), an aluminum-doped zinc oxide (ZnO:Al; AZO), a fluorine-doped tin oxide, or a niobium-doped anatase.

The first insulating film 170 may be disposed between the transparent electrode 150 and the second surface 110b of the substrate 110 and between the transparent electrode 150 and the inner surface of the recess 200. As a result, the transparent electrode 150 may be electrically insulated from the substrate 110, that is, the pixel area (PXR), by the first insulating film 170. In one or more embodiments, the first insulating film 170 may also be disposed between the buried conductive pattern 135 and the transparent electrode 150. In other words, the first insulating film 170 may cover the second surface 110b of the substrate 110, the inner surface of the recess 200, and a top surface of the deep trench isolator 130.

The first insulating film 170 may be formed of a transparent insulating material. For example, the first insulating film 170 may include a silicon-based insulating material (e.g., a silicon oxide, a silicon nitride, and/or a silicon oxynitride) and/or a high dielectric material (e.g., a hafnium oxide and/or an aluminum oxide).

The first insulating film 170 may have a single-layer structure or a multi-layer structure. In one or more embodiments, the first insulating film 170 may perform a function as an antireflective layer and/or a function as a fixed charge layer. In one or more embodiments, when the first insulating film 170 is used as the antireflective layer, the first insulating film 170 may include, for example, one of a hafnium oxide (HfOx), a zirconium oxide (ZrO₂), and an aluminum oxide (Al₂O₃). In this case, the first insulating film 170 may prevent reflection of light so that light incident on the second surface 110b of the substrate 110 may smoothly reach the photoelectric conversion area 120. In one or more embodiments, when the first insulating film 170 is used as the fixed charge layer, the first insulating film 170 may have negative fixed charges. In this case, the first insulating film 170 may include a metal oxide or a metal fluoride containing at least one of hafnium, zirconium, tantalum, yttrium, or lanthanide. In one or more embodiments, the first insulating film 170 may include the fixed charge layer and the antireflective layer that are sequentially stacked.

The second insulating film 310 may be disposed between the transparent electrode 150 and the micro lens ML. The second insulating film 310 may cover a top surface of the transparent electrode 150. In one or more embodiments, when the transparent electrode 150 is conformally formed along the inner surface of the recess 200, the second insulating film 310 may fill the remaining area of the recess 200.

The second insulating film 310 may be formed of a transparent insulating material. For example, the first insulating film 170 may include a silicon-based insulating material (e.g., a silicon oxide, a silicon nitride, and/or a silicon oxynitride) and/or a high dielectric material (e.g., a hafnium oxide and/or an aluminum oxide).

The microlens ML may be disposed on the second insulating film 310. At least a portion of the microlens ML may vertically overlap the photoelectric conversion area 120. The microlens ML may concentrate light incident toward the substrate 110 and may include a spherical lens, an aspherical lens, or a combination thereof.

The microlens ML may be transparent and may transmit light. The microlens ML may include an organic material such as polymer. For example, the microlens ML may include a photoresist material or a thermosetting resin.

When the light detection sensor having the above-described structure operates, a negative bias voltage may be applied to the transparent electrode 150. That is, the transparent electrode 150 is configured to receive a negative bias voltage. As a result, dark current that may be caused by defects in the second surface 110b and the inner surface of the recess 200 of the pixel area PXR may be reduced or minimized.

The light detection sensor may be implemented as one of various light sensors. For example, the light detection sensor may be an infrared (IR) sensor or an image sensor. When the light detection sensor is the image sensor, a color filter may be disposed between the microlens ML and the second insulating film 310. Embodiments in which the light detection sensor is the image sensor will be described in detail below.

According to the light detection sensor, at least one recess 200 may be recessed from the second surface 110b of the substrate 110, which is the light incident surface, into the pixel area PXR. The recess 200 may generate diffraction or scattering of the incident light, thereby improving light receptivity of the photoelectric conversion area 120. In addition, the transparent electrode 150 may be provided on the inner surface of the recess 200 and the second surface 110b with the first insulating film 170 interposed therebetween, and a negative bias voltage may be applied to the transparent electrode 150. Accordingly, dark current caused from the second surface 110b of the substrate 110 and the inner surface of the recess 200 may be reduced or minimized.

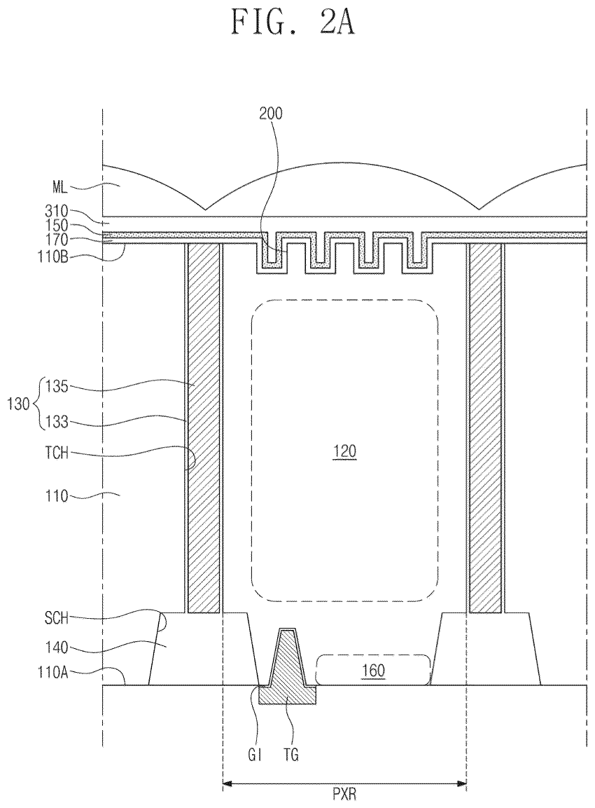

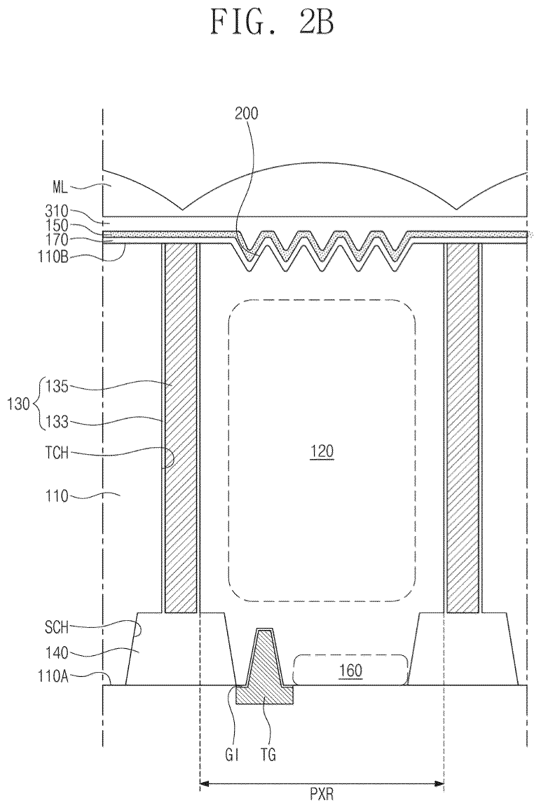

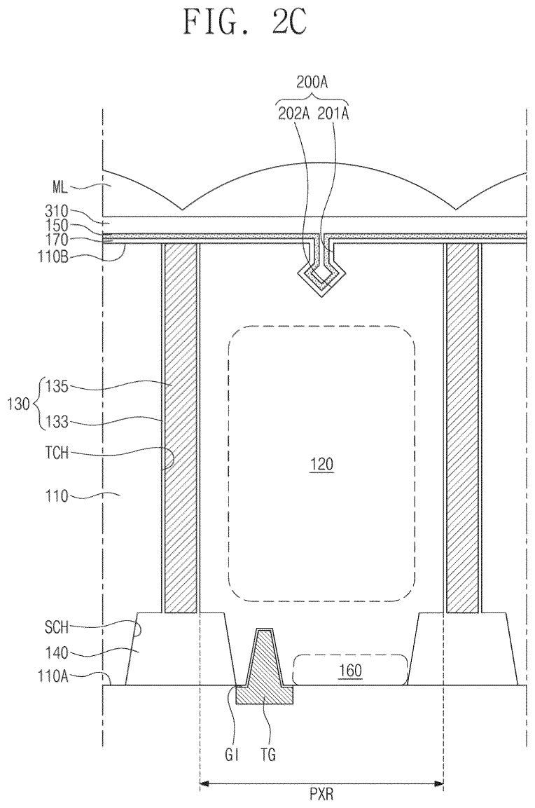

FIGS. 2A to 2C are cross-sectional views of the light detection sensors according to one or more embodiments of the present disclosure. Hereinafter, for convenience of explanation, differences between the above-described embodiment and the present embodiments will mainly be described.

Referring to FIG. 2A, the plurality of recesses 200 may be provided in the pixel area PXR. A cross-section of each of the recesses 200 may have a substantially rectangular shape. Each of the recesses 200 may have one of various shapes from a plan view. For example, a planar shape of each of the recesses 200 may have a circular shape, an elliptical shape, a polygonal shape, or a bar shape. When each of the recesses 200 has a circular, elliptical, or polygonal shape, the recesses 200 may be arranged two-dimensionally in two directions parallel to the second surface 110b of the substrate 110. The two directions may intersect each other. When each of the recesses 200 has a bar shape, the recesses 200 may be arranged in one direction parallel to the second surface 110b of the substrate 110.

In one or more embodiments, a size (e.g., a width) of each of the recesses 200 and/or an interval between the recesses 200 may be adjusted to improve light receptivity of light having a specific wavelength. That is, when the light incident on the photoelectric conversion area 120 has a specific wavelength, the width of each of the recesses 200 and/or the interval between the recesses 200 may be adjusted to improve light receptivity of the light.

In FIG. 2A, four recesses 200 are shown in the pixel area PXR, but the present disclosure is not limited thereto. In one or more embodiments, a pair of recesses 200 may be formed in both edge areas of the pixel area PXR, respectively and each of the pair of recesses 200 may have a rectangular cross-section.

The first insulating film 170 and the transparent electrode 150 may be provided on the second surface 110b of the substrate 110 and the inner surfaces of the plurality of recesses 200.

Referring to FIG. 2B, the plurality of recesses 200 may be provided in the pixel area PXR, and a cross-section of each of the recesses 200 may have a substantially inverted triangular shape. The first insulating film 170 and the transparent electrode 150 may be provided on the inner surfaces of the recesses 200 and the second surface 110b of the substrate 110.

Other features of the light detection sensor of FIG. 2B may be the same/similar to the light detection sensor of FIG. 2A.

Referring to FIG. 2C, a recess 200a may include an upper part 201a and a lower part 202a. A width of the upper part 201a of the recess 200a may differ from a width of the lower part 202a of the recess 200a. In one or more embodiments, a width of a lower part of the at least one recess in a first direction parallel to the second surface 110b may be greater than a width of an upper part of the at least one recess in the first direction. For example, the width of the lower part 202a of recess 200a may be greater than the width of the upper part 201a of recess 200a. However, the present disclosure is not limited thereto. For example, the width of the upper part 201a of recess 200a may be greater than the width of the lower part 202a of recess 200a.

The recess 200a may have one of various shapes from a plan view. For example, a planar shape of the recess 200a may have a circular shape, an elliptical shape, a polygonal shape, a cross shape, or a bar shape.

In FIG. 2C, a cross-section of the lower part 202a of the recess 200a is shown as a diamond shape, but is not limited thereto. In one or more embodiments, the cross-section of the lower part 202a of the recess 200a may have one of various other shapes (e.g., a circular shape, an elliptical shape, a polygonal shape, etc.).

In FIG. 2C, one recess 200a is shown in the pixel area PXR, but the present disclosure is not limited thereto. In one or more embodiments, the plurality of recesses 200a may be provided in the pixel area PXR.

The first insulating film 170 and the transparent electrode 150 may be provided on the inner surface of the recess 200a and the second surface 110b of the substrate 110.

The cross-sectional shape of the recess 200 is not limited to the shapes of the cross-sections of the recesses 200 and 200a described above in FIGS. 1 and 2A to 2C. The cross-section of the recess 200 may have one of various other shapes.

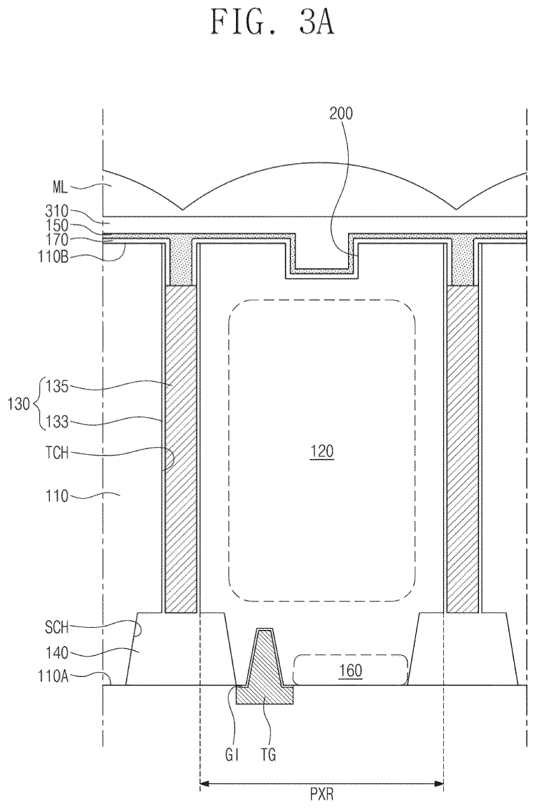

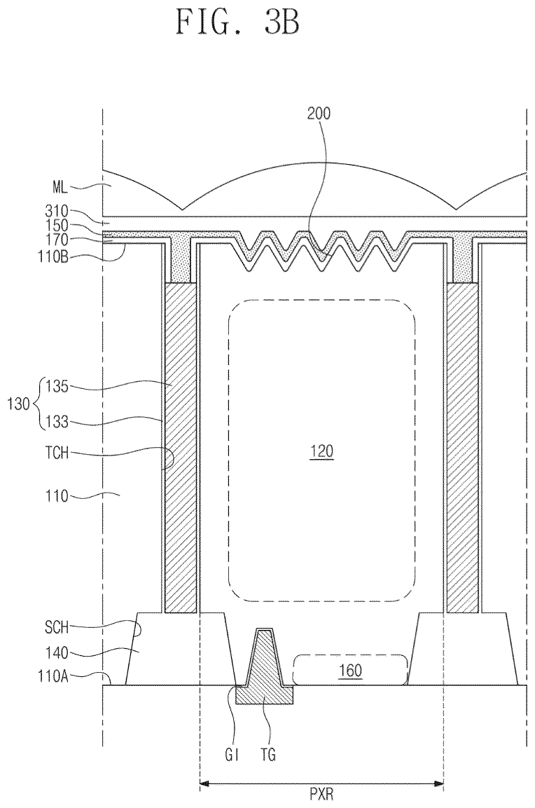

FIGS. 3A and 3B are cross-sectional views of light detection sensors according to one or more embodiments of the present disclosure. Hereinafter, for convenience of explanation, differences between the above-described embodiments and the present embodiments will mainly be described.

Referring to FIGS. 3A and 3B, a top surface of the buried conductive pattern 135 of the deep trench isolator 130 may be recessed from the second surface 110b of the substrate 110. The first insulating film 170 and the transparent electrode 150 may extend into the deep trench TCH, and the transparent electrode 150 may pass through the first insulating film 170 within the deep trench TCH to be in contact with the buried conductive pattern 135. In one or more embodiments, a first end of the buried conductive pattern 135 may be uneven, and the first end may face the first surface 110a of the substrate 110.

The first insulating film 170 may be disposed between the substrate 110 and the transparent electrode 150 in the deep trench TCH. Additionally, the insulating liner 133 may also be disposed between the substrate 110 and the transparent electrode 150 within the deep trench TCH. Accordingly, the transparent electrode 150 may be electrically connected to the buried conductive pattern 135 but may be electrically insulated from the substrate 110.

As a result, a negative bias voltage may be applied to both the transparent electrode 150 and the buried conductive pattern 135 through the transparent electrode 150 or the buried conductive pattern 135. That is, the transparent electrode 150 and the buried conductive pattern 135 may be configured to receive a negative bias voltage. By applying the negative bias voltage to the buried conductive pattern 135, dark current caused by defects in the inner side surface of the deep trench TCH may be reduced or minimized.

A cross-section of the recess 200 in FIG. 3A may have a substantially rectangular shape, and a cross-section of the recess 200 in FIG. 3B may have a substantially inverted triangular shape. However, the present disclosure is not limited thereto. In one or more embodiments, the recess 200 of FIG. 2A or FIG. 2C may be applied to FIG. 3A. In one or more embodiments, the cross-section of the recess 200 in FIG. 3A may have a different shape from the cross-sections of the recesses 200 in FIGS. 2A to 2C.

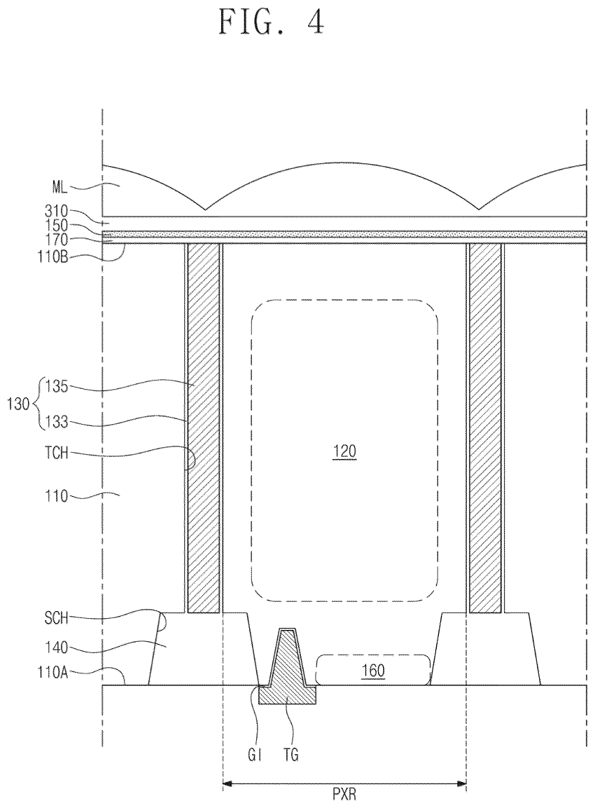

FIG. 4 is a cross-sectional view of a light detection sensor according to one or more embodiments of the present disclosure. Hereinafter, for convenience of explanation, differences between the present embodiment and the above-described embodiments will mainly be described.

Referring to FIG. 4, the recess 200 may be omitted from the pixel area PXR. The second surface 110b of the pixel area PXR may be flat, and the first insulating film 170 and the transparent electrode 150 may be sequentially stacked on the second surface 110b of the pixel area PXR. Accordingly, bottom surfaces of the first insulating film 170 and the transparent electrode 150 may also be substantially flat.

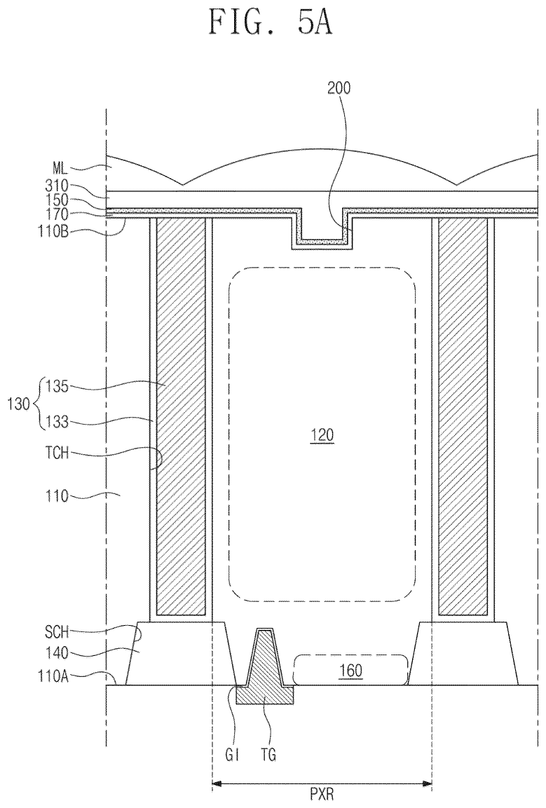

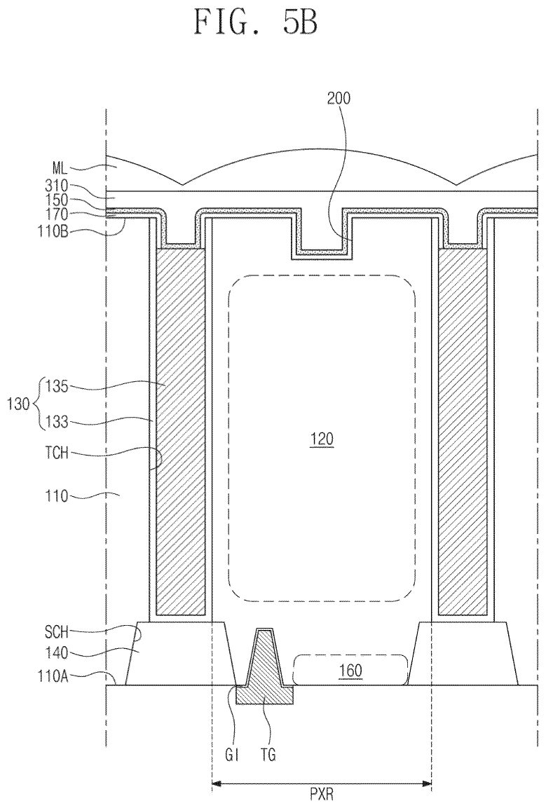

FIGS. 5A and 5B are cross-sectional views of light detection sensors according to one or more embodiments of the present disclosure. Hereinafter, for convenience of explanation, differences between the present embodiments and the above-described embodiments will mainly be described.

Referring to FIGS. 5A and 5B, the deep trench TCH may extend from the second surface 110b of the substrate 110 to the shallow trench isolator SCH. The insulating liner 133 of the deep trench isolator 130 may extend to be disposed between the buried conductive pattern 135 and the shallow trench isolator 140. At least one recess 200 may be recessed from the second surface 110b of the substrate 110 into the pixel area PXR.

Referring to FIG. 5A, the transparent electrode 150 may be provided on the second surface 110b of the substrate 110 and the inner surface of the recess 200. The first insulating film 170 may be disposed between the second surface 110b of the substrate 110 and the transparent electrode 150, between the inner surface of the recess 200 and the transparent electrode 150, and between the buried conductive pattern 135 and the transparent electrode 150. That is, the first insulating film 170 may cover the second surface 110b of the substrate 110, the inner surface of the recess 200, and the top surface of the deep trench isolator 130.

Referring to FIG. 5B, the top surface of the buried conductive pattern 135 may be recessed from the second surface 110b of the substrate 110. The first insulating film 170 and the transparent electrode 150 may extend into the deep trench TCH, and the transparent electrode 150 may pass through the first insulating film 170 within the deep trench TCH to be in contact with the buried conductive pattern 135. The first insulating film 170 may be disposed between the transparent electrode 150 and the inner side surface of the deep trench TCH. Additionally, the insulating liner 133 may be disposed between the transparent electrode 150 and the inner side surface of the deep trench TCH. As a result, the transparent electrode 150 may be electrically connected to the buried conductive pattern 135 but may be electrically insulated from the substrate 110. Accordingly, a negative bias voltage may be applied to both the transparent electrode 150 and the buried conductive pattern 135 through the transparent electrode 150 or the buried conductive pattern 135.

The recess 200 of FIG. 1 is applied to the light detection sensors of FIGS. 5A and 5B, but the disclosure is not limited thereto. In one or more embodiments, one of the recesses 200 and 200a of FIGS. 2A to 2C may be applied to the light detection sensors of FIGS. 5A and 5B. In one or more embodiments, the cross-section of the recess 200 in the light detection sensor of FIG. 5A or 5B may have a different shape from the cross-sections of the recesses 200 and 200a in FIGS. 2A to 2C.

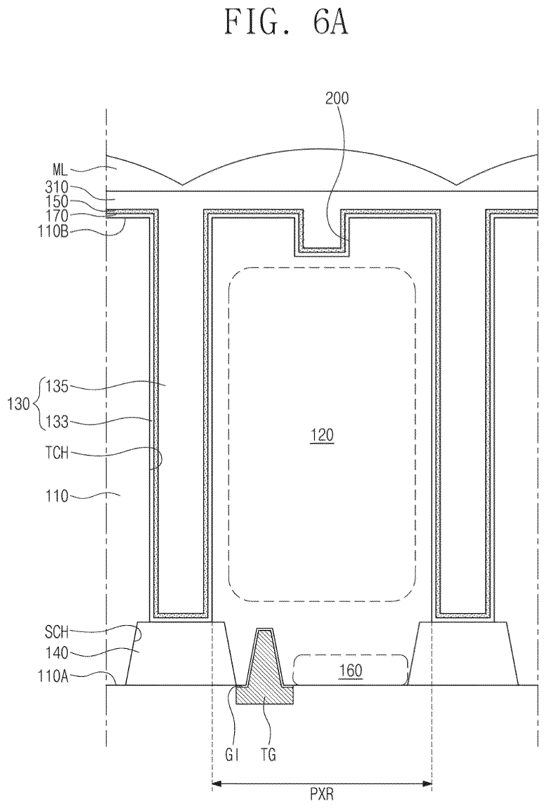

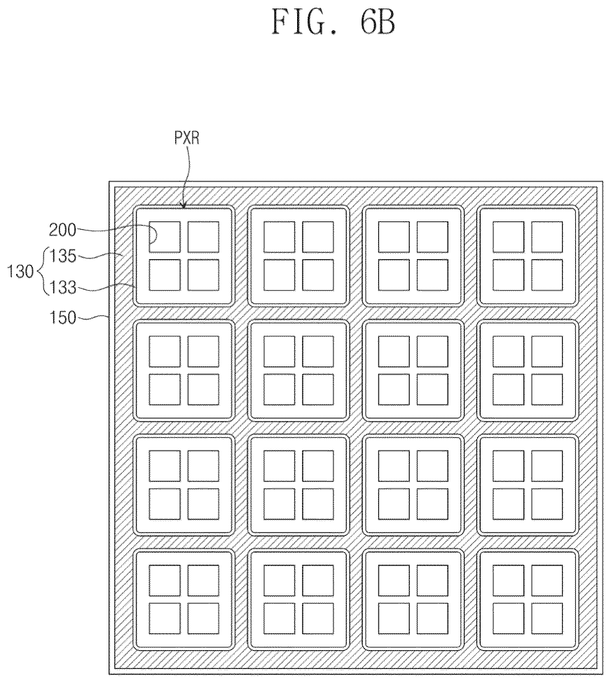

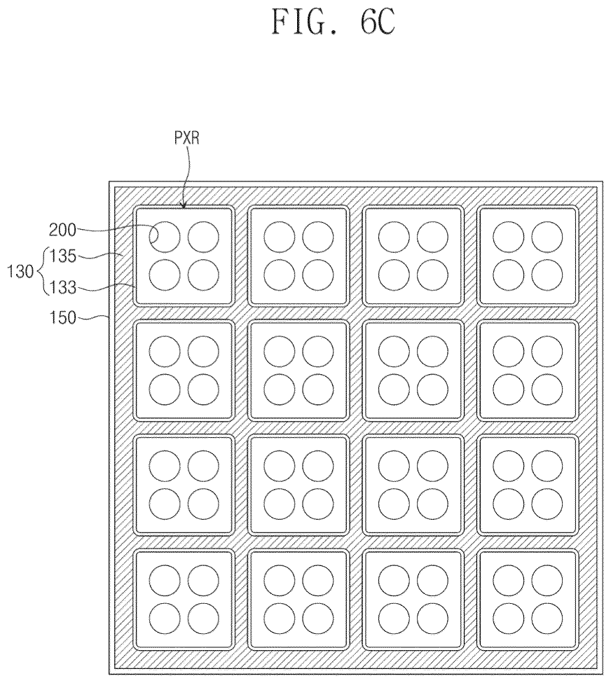

FIG. 6A is a cross-sectional view of the light detection sensor according to one or more embodiments of the present disclosure. Hereinafter, for convenience of explanation, differences between the present embodiment and the above-described embodiments will mainly be described.

Referring to FIG. 6A, the deep trench TCH may extend from the second surface 110b of the substrate 110 toward the shallow trench isolator 140. In the present embodiment, the above-described buried conductive pattern 135 may be omitted.

The first insulating film 170 and the transparent electrode 150 covering the inner surface of the recess 200 and the second surface 110b of the substrate 110 may extend into the deep trench TCH. Specifically, the first insulating film 170 and the transparent electrode 150 may extend along the inner surface of the deep trench TCH. In particular, the first insulating film 170 and the transparent electrode 150 may cover the inner side surface of the deep trench TCH. The second insulating film 310 may extend to fill the remaining area of the deep trench TCH.

The first insulating film 170, the transparent electrode 150, and the second insulating film 310 in the deep trench TCH may configure the deep trench isolator. The first insulating film 170 may be disposed between the transparent electrode 150 and the inner side surface of the deep trench TCH, thereby electrically insulating the transparent electrode 150 from the substrate 110 even within the deep trench TCH.

According to the present embodiment, the transparent electrode 150 may be provided on the inner surface of the recess 200 and the inner surface (particularly, the inner side surface) of the deep trench TCH. Accordingly, when a negative bias voltage may be applied to the transparent electrode, dark current that may be caused by defects in the inner surface of the recess 200 and in the inner side surface of the deep trench TCH may be reduced or minimized.

The recess 200 of FIG. 6A may correspond to the recess 200 of FIG. 1. However, the embodiments of the present disclosure are not limited thereto. At least one of the recesses 200 and 200a of FIGS. 2A to 2C or other forms of recesses may be applied to FIG. 6A.

As described above, a planar shape and an arrangement of the recess(es) may be modified in various ways. Hereinafter, the planar shapes and arrangements of the recesses according to one or more embodiments will be described.

FIGS. 6B and 6C are plan views showing light detection sensors according to one or more embodiments of the present disclosure.

Referring to FIGS. 6B and 6C, the recesses 200 may be arranged in an M×N matrix form (here, “M” is a natural number greater than or equal to 2, and “N” is a natural number greater than or equal to 2) within each of the pixel areas PXR. For example, as shown in FIGS. 6B and 6C, four recesses 200 may be arranged in a 2×2 matrix form within each of the pixel areas PXR. In one or more embodiments, as shown in FIG. 6B, a planar shape of each of the recesses 200 may be a rectangular shape. Alternatively, as shown in FIG. 6C, the planar shape of each of the recesses 200 may be a circular shape. However, the present disclosure is not limited thereto. In one or more embodiments, from a plan view as described above, the shape of the recess 200 may be modified in various ways. For example, the planar shape of the recess 200 may be an elliptical shape, a polygonal shape, a cross shape, or a bar shape.

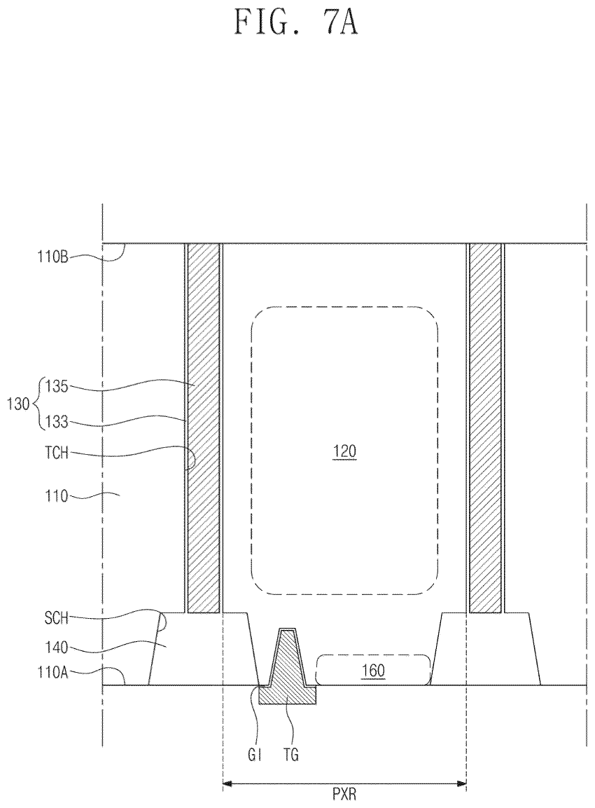

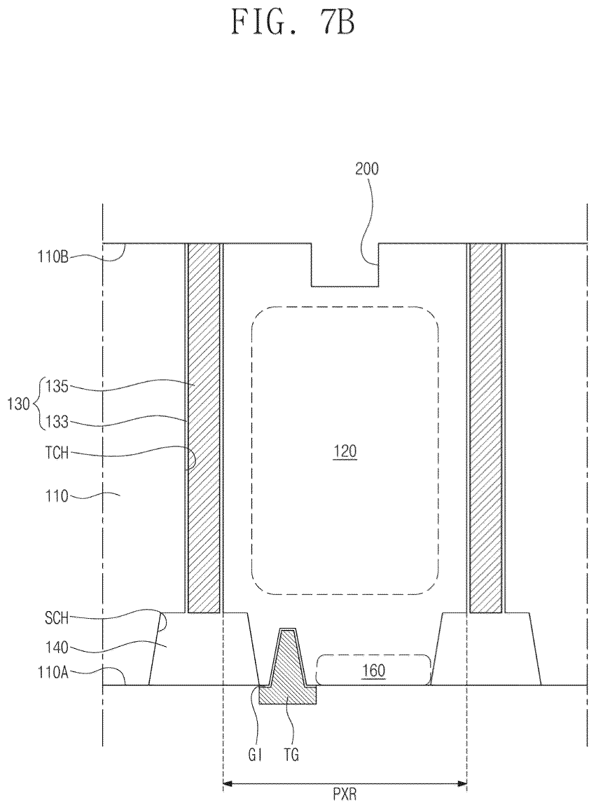

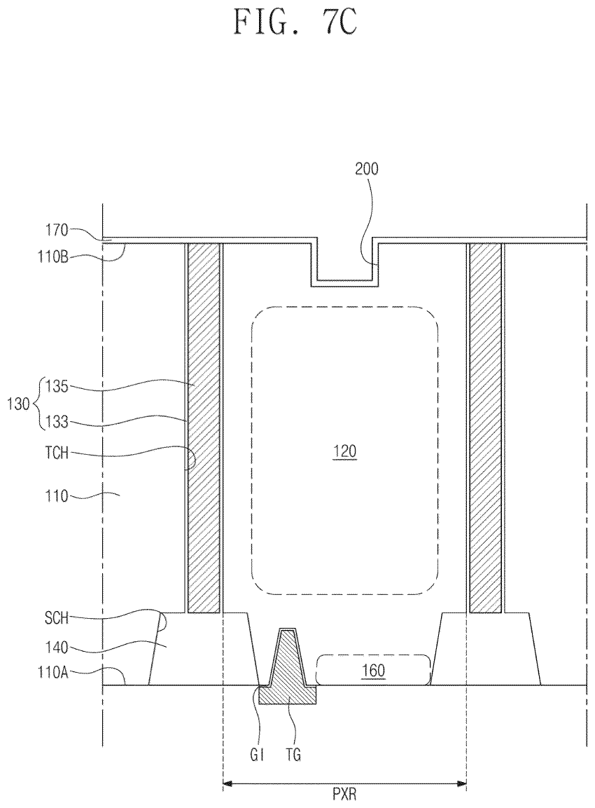

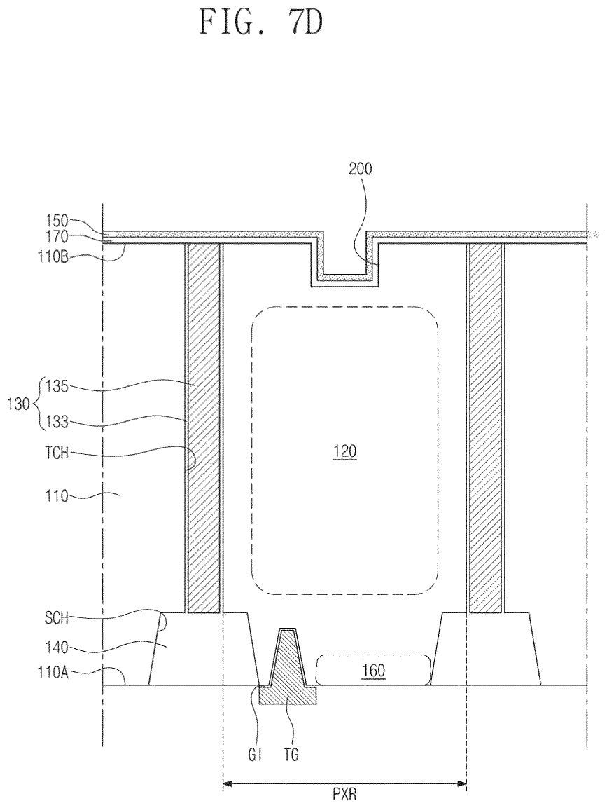

FIGS. 7A to 7D are cross-sectional views sequentially showing a manufacturing method of the light detection sensor according to one or more embodiments of the present disclosure.

Referring to FIG. 7A, the shallow trench SCH may be formed from the first surface 110a of the substrate 110 toward the second surface 110b of the substrate 110, and the deep trench TCH may be formed from the first surface 110a of the substrate 110 toward the second surface 110b of the substrate 110. The deep trench TCH may define the pixel area PXR, and the shallow trench SCH may define the active area. An insulating liner film may be conformally formed on the first surface 110a of the substrate 110 having the shallow trench SCH and the deep trench TCH, and a buried conductive film may be formed on the insulating liner film to fill the shallow trench SCH and the deep trench TCH. The buried conductive film may be etched to form the buried conductive pattern 135 in the deep trench TCH, and an insulating material may be formed to fill the shallow trench SCH. The insulating material outside the shallow trench SCH and the insulating liner film may be removed to form the insulating liner 133 in the deep trench TCH and the shallow trench isolator 140 in the shallow trench SCH. The insulating liner 133 and the buried conductive pattern 135 may configure the deep trench isolator 130. The insulating liner film may be formed by at least one of an oxidation process or a deposition process, the buried conductive film may be formed by the deposition process, and the insulating material may be formed by the deposition process.

The photoelectric conversion area 120 may be formed within the pixel area PXR. A gate trench may be formed in the active area and the transfer gate TG may be formed on the active area with the gate dielectric film GI interposed therebetween. The transfer gate TG may fill the gate trench. The floating diffusion region 160 may be formed within the active area of one side of the transfer gate TG.

The substrate 110 may be turned over and the second surface 110b of the substrate 110 may be polished to expose the buried conductive pattern 135. In one or more embodiments, the second surface 110b of the substrate 110 may be polished through a chemical mechanical polishing (CMP) process. A hydrogen/deuterium annealing process may be performed to heal defects (e.g., dangling bonds) in the polished second surface 110b of the substrate 110.

Referring to FIG. 7B, at least one recess 200 may be formed to be recessed from the second surface 110b of the substrate 110. The plurality of recesses 200 may be formed as shown in FIG. 2A or 2B. The recess 200 may be formed as shown in FIG. 2C. The recess may be formed using an anisotropic etching process or an isotropic etching process.

Referring to FIG. 7C, the first insulating film 170 may be conformally formed on the second surface 110b of the substrate 110 and the inner surface of the recess 200. The first insulating film 170 may be formed using at least one of the deposition process or the oxidation process.

Referring to FIG. 7D, the transparent electrode 150 may be formed on the first insulating film 170. The transparent electrode 150 may cover the second surface 110b of the substrate 110 and the inner surface of the recess 200. The transparent electrode 150 may be formed through the deposition process.

Referring back to FIG. 1, the second insulating film 310 may be formed on the transparent electrode 150. The second insulating film 310 may fill the remaining area of the recess 200. The microlens ML may be formed on the second insulating film 310.

Hereinafter, a manufacturing method of the light detection sensor of FIG. 3A or FIG. 3B will be described. In the structure of FIG. 7A or FIG. 7B, the exposed buried conductive pattern 135 may be etched. Accordingly, a top surface of the buried conductive pattern 135 may be recessed from the second surface 110b of the substrate 110. Subsequently, the first insulating film 170 may be conformally formed on the second surface 110b of the substrate 110 and the first insulating film 170 on the recessed top surface of the buried conductive pattern 135 may be removed. Accordingly, the recessed top surface of the buried conductive pattern 135 may be exposed again. Subsequently, the transparent electrode 150 may be formed on the first insulating film 170. At this time, the transparent electrode 150 may come into contact with the exposed top surface of the buried conductive pattern 135. Subsequent processes may be the same as those described with reference to FIG. 1.

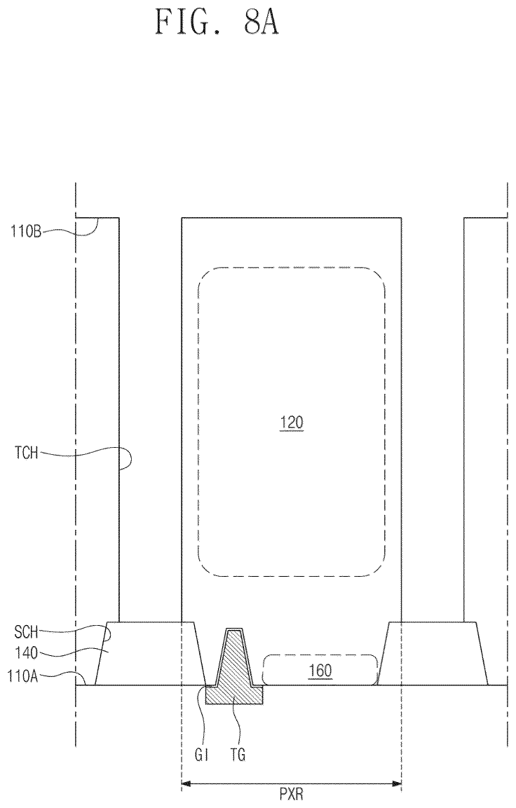

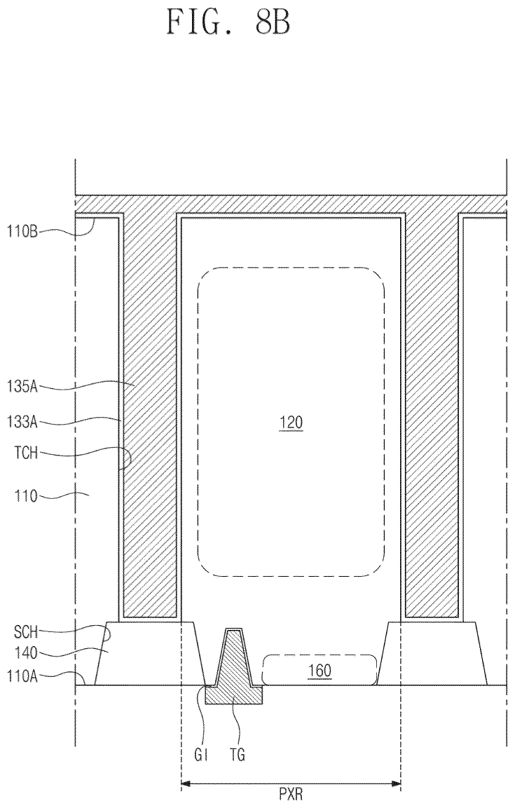

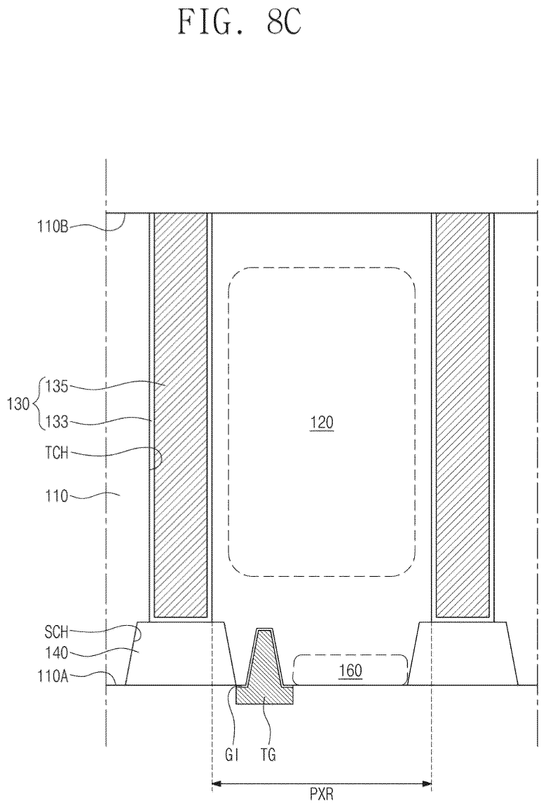

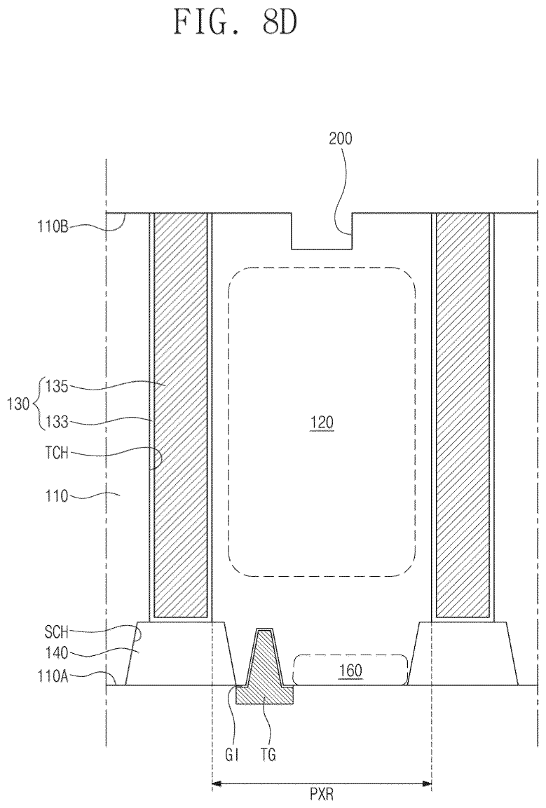

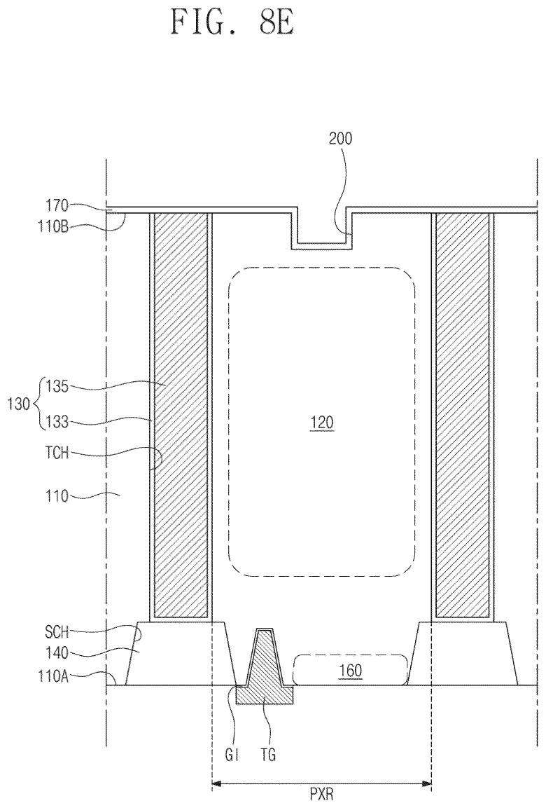

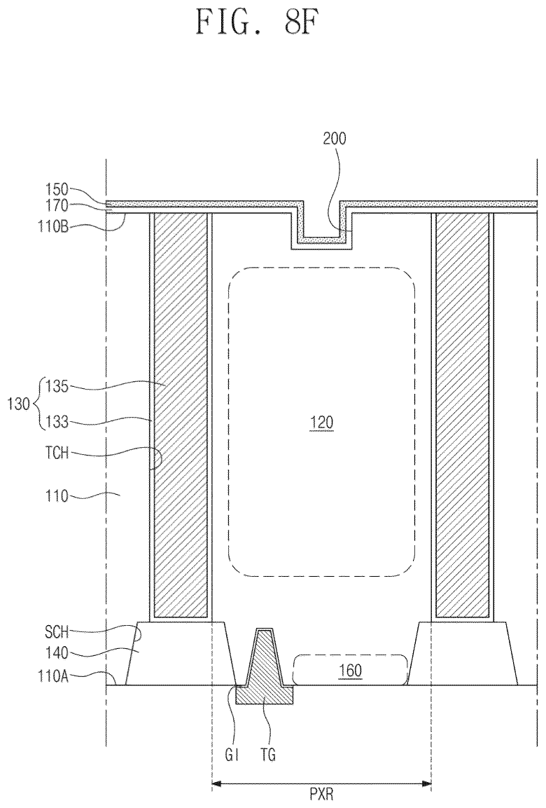

FIGS. 8A to 8F are cross-sectional views sequentially showing a manufacturing method of the light detection sensor according to one or more embodiments of the present disclosure.

Referring to FIG. 8A, a patterning process may be performed on the first surface 110a of the substrate 110 to form the shallow trench SCH and the shallow trench isolator 140 may be formed in the shallow trench SCH. The photoelectric conversion area 120 may be formed in the substrate 110. The transfer gate TG and the gate dielectric film GI may be formed on the active area defined by the shallow trench isolator 140 and the floating diffusion region 160 may be formed within the active area of one side of the transfer gate TG.

Thereafter, the substrate 110 may be turned over, and the patterning process may be performed on the second surface 110b of the substrate 110 to form the deep trench TCH in the substrate 110. The deep trench TCH may extend from the second surface 110b toward the first surface 110a. As shown in FIG. 8A, the deep trench TCH may expose a portion of the shallow trench isolator 140. Alternatively, a bottom surface of the deep trench TCH may be spaced apart from the shallow trench isolator 140.

In one or more embodiments, before forming the deep trench TCH, a polishing process may be performed on the second surface 110b of the substrate 110 to reduce a thickness of the substrate 110.

Referring to FIG. 8B, the insulating liner film 133a may be conformally formed on the second surface 110b of the substrate 110 and the inner surface of the deep trench TCH. A buried conductive film 135a may be formed on the insulating liner film 133a to fill the deep trench TCH.

Referring to FIG. 8C, an etching process may be performed on the buried conductive film 135a to expose the substrate 110. As a result, the deep trench isolator 130 including the buried conductive pattern 135 and the insulating liner 133 may be formed. The etching process may be performed through an etch-back process or a chemical mechanical polishing (CMP) process. A hydrogen/deuterium annealing process may be performed to heal defects (e.g., dangling bonds) in the second surface 110b of the substrate 110.

Referring to FIG. 8D, the patterning process may be performed on the second surface 110b of the pixel area PXR to form at least one recess 200 in the pixel area PXR.

Referring to FIG. 8E, the first insulating film 170 may be formed on the second surface 110b of the substrate 110 and the inner surface of the recess 200. The first insulating film 170 may be formed using at least one of the deposition process or the oxidation process.

Referring to FIG. 8F, the transparent electrode 150 may be formed on the first insulating film 170. The transparent electrode 150 may be formed using the deposition process.

Referring back to FIG. 5A, the second insulating film 310 may be formed on the transparent electrode 150 to fill the recess 200. The microlens ML may be formed on the second insulating film 310.

Hereinafter, a manufacturing method of the light detection sensor of FIG. 5B will be described. In the structure of FIG. 8C or FIG. 8D, the top surface of the buried conductive pattern 135 may be etched. Accordingly, the top surface of the buried conductive pattern 135 may be recessed from the second surface 110b of the substrate 110. Subsequently, the first insulating film 170 may be formed on the second surface 110b of the substrate 110 having the recess 200 and the first insulating film 170 on the recessed top surface of the buried conductive pattern 135 may be removed to expose the recessed top surface of the buried conductive pattern 135. Subsequently, the transparent electrode 150 may be formed on the first insulating film 170. At this time, the transparent electrode 150 may come into contact with the exposed top surface of the buried conductive pattern 135. Subsequent processes may be the same as those described with reference to FIG. 5A.

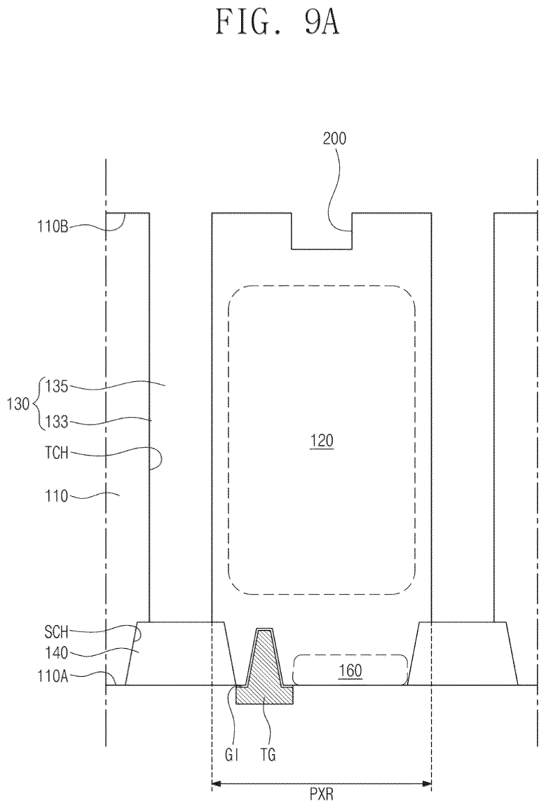

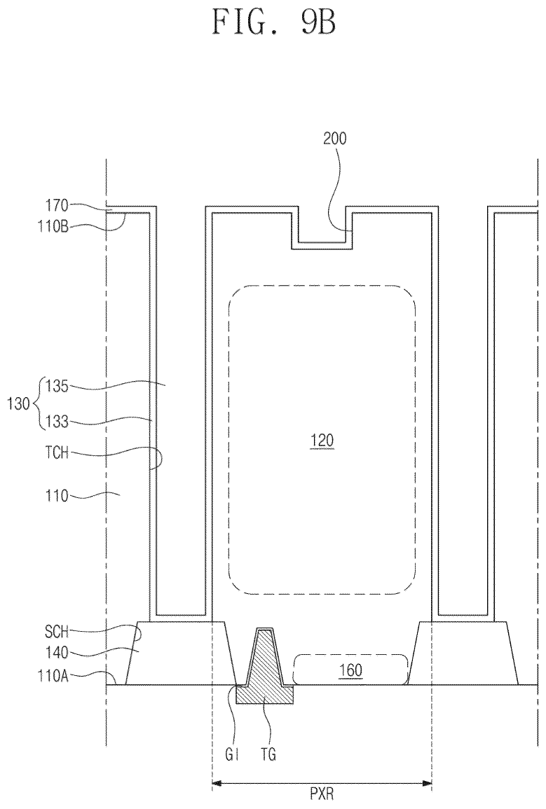

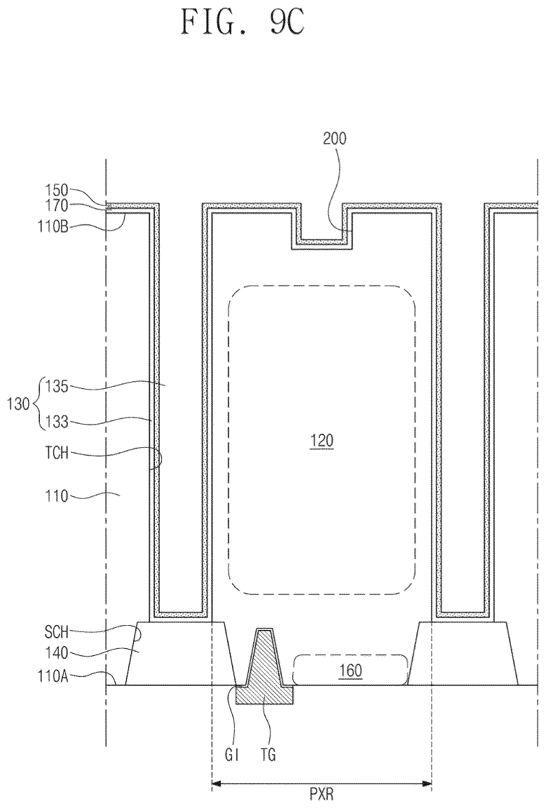

FIGS. 9A to 9D are cross-sectional views sequentially showing a manufacturing method of the light detection sensor according to one or more embodiments of the present disclosure.

Referring to FIG. 9A, a first patterning process may be performed on the second surface 110b of the substrate 110 to form the deep trench TCH in the substrate 110 and a second patterning process may be performed on the second surface 110b of the substrate 110 to form at least one recess 200 in the substrate 110.

Referring to FIG. 9B, the first insulating film 170 may be conformally formed on the second surface 110b of the substrate 110, the inner surface of the recess 200, and the inner surface of the deep trench TCH. That is, the first insulating film 170 may be provided on the second surface 110b of the substrate 110 and may cover the inner surface of the deep trench TCH and the inner surface of the recess 200. The first insulating film 170 may be formed using at least one of the oxidation process or the deposition process.

Referring to FIG. 9C, the transparent electrode 150 may be formed on the first insulating film 170. The transparent electrode 150 may cover the second surface 110b of the substrate 110, the inner surface of the recess 200, and the inner surface of the deep trench TCH.

Referring back to FIG. 6A, the second insulating film 310 may be formed on the transparent electrode 150. The second insulating film 310 may fill the remaining area of the deep trench TCH and the remaining area of the recess 200. The microlens ML may be formed on the second insulating film 310.

Hereinafter, an embodiment in which the light detection sensor is a CMOS image sensor will be described in more detail.

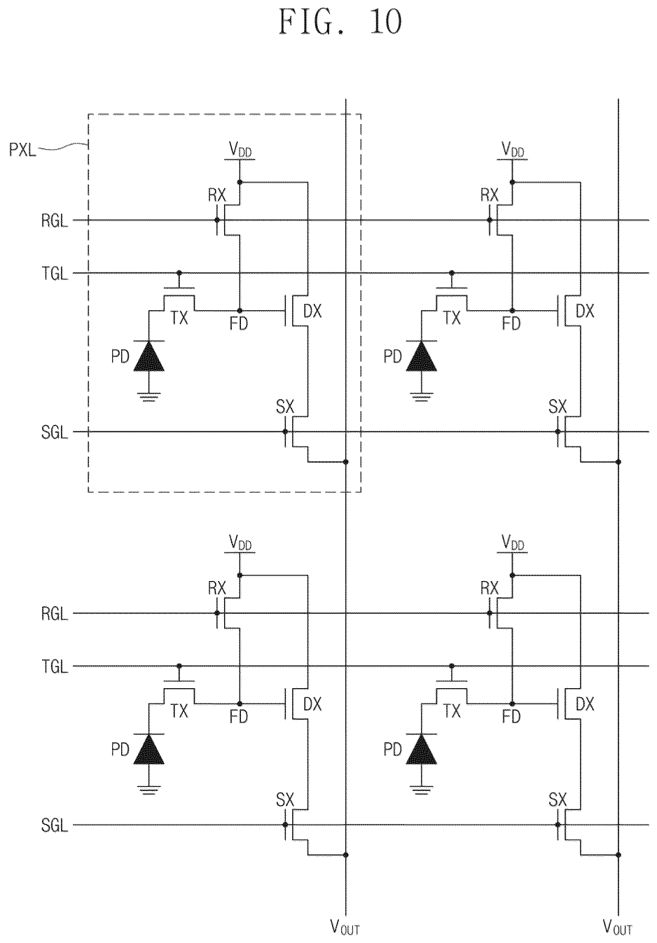

FIG. 10 is a circuit diagram of pixels of a pixel array in the light detection sensor according to one or more embodiments of the present disclosure.

Referring to FIG. 10, the pixel array may include a plurality of pixels PXL, and the pixels PXL may be arranged in a matrix form. Each of the pixels PXL may include a transfer transistor TX and logic transistors RX, SX, and DX. The logic transistors RX, SX, and DX may include a reset transistor RX, a selection transistor SX, and a source follower transistor DX. A transfer gate of the transfer transistor TX may be connected to a transfer gate line TGL. Each of the pixels PXL may further include a photoelectric conversion element PD and a floating diffusion region FD.

The photoelectric conversion element PD may generate and accumulate photocharges in proportion to amount of light incident from outside. The photoelectric conversion element PD may include a photodiode, a phototransistor, a photogate, a pinned photodiode, or a combination thereof. The transfer transistor TX may transfer the photocharges generated from the photoelectric conversion element PD to the floating diffusion region FD. The floating diffusion region FD may receive and cumulatively store the photocharges generated from the photoelectric conversion element PD.

A gate of the source follower transistor DX may be connected to the floating diffusion region FD. A drain electrode of the source follower transistor DX may be connected to a power voltage VDD. The source follower transistor DX may be controlled according to the amount of photocharges accumulated in the floating diffusion region FD.

The reset transistor RX may periodically reset the charges accumulated in the floating diffusion region FD. A gate of the reset transistor RX may be connected to a reset gate line RGL. A source electrode of the reset transistor RX may be connected to the floating diffusion region FD, and a drain electrode of the reset transistor RX may be connected to the power voltage VDD. When the reset transistor RX is turned on, the power voltage VDD may be applied to the floating diffusion region FD through the reset transistor RX. In other words, when the reset transistor RX is turned on, the charges accumulated in the floating diffusion region FD may be discharged by the power voltage VDD, thereby resetting the floating diffusion region FD.

The source follower transistor DX may serve as a source follower buffer amplifier. The source follower transistor DX may amplify a potential change in the floating diffusion region FD and output the amplified potential change to an output line VOUT.

A gate of the selection transistor SX may be connected to a selection gate line SGL. A drain electrode of the selection transistor SX may be connected to the source electrode of the source follower transistor DX, and a source electrode of the selection transistor SX may be connected to the output line Vour. The pixels PXL to be readout in row unit may be selected by a selection signal applied through the selection gate line SGL corresponding to the selection transistors SX. When the selection transistor SX is turned on, the potential change amplified by the source follower transistor DX may be output to the output line Vour through the selection transistor SX.

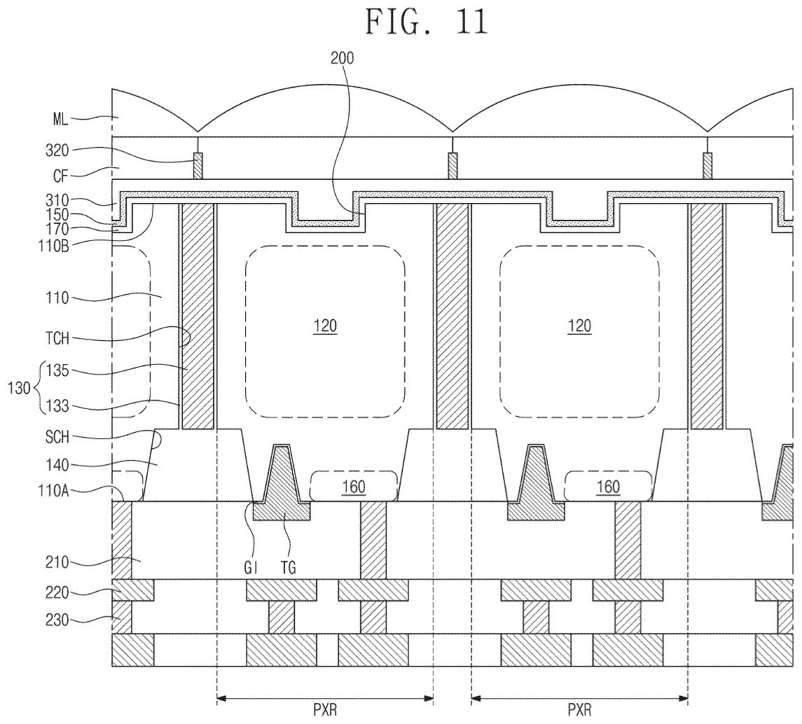

FIG. 11 is a cross-sectional view showing the light detection sensor according to one or more embodiments of the present disclosure. Hereinafter, for convenience of explanation, differences between the present embodiment and the above-described embodiments will mainly be described.

The light detection sensor according to one or more embodiments of the present disclosure may include the substrate 110, the deep trench isolator 130, the shallow trench isolator 140, the recess 200, the transparent electrode 150, the first insulating film 170, the second insulating film 310, the color filter CF, a grid pattern 320, and the microlens ML.

The deep trench isolator 130 may be disposed in the substrate 110 to define the plurality of pixel areas PXR. The photoelectric conversion area 120 may be disposed in each of the pixel areas PXR.

In one or more embodiments, the shallow trench isolator 140 may define the plurality of active areas in each of the pixel areas PXR and the transfer gate TG may be disposed on one of the plurality of active areas with the gate dielectric film GI interposed therebetween. As described above, the transfer gate TG may fill the gate trench formed within the one active area. The floating diffusion region 160 may be disposed within the one active area of one side of the transfer gate TG. The transfer transistor of FIG. 10 may include the transfer gate TG. The gates of the logic transistors RX, SX, and DX of FIG. 10 may be disposed on other ones of the plurality of active areas. Source/drain areas may be disposed in corresponding active areas on both sides of each of the gates of the logic transistors.

Interlayer insulating films 210 may be stacked on the first surface 110a of the substrate 110, and wirings 220 and contact plugs 230 may be disposed in the interlayer insulating films 210. To implement the pixel PXL of FIG. 10, the wirings 220 and the contact plugs 230 may be properly connected to the gates, the floating diffusion region 160, and the source/drain areas.

As described above, at least one recess 200 may be recessed from the second surface 110b of the substrate 110 into each of the pixel areas PXR. The first insulating film 170 and the transparent electrode 150 may be sequentially stacked on the second surface 110b of the substrate 110 and the inner surface of the recess 200. The second insulating film 310 may be provided on the transparent electrode 150 to fill the remaining area of the recess 200.

The grid pattern 320 may be provided on the second insulating film 310 and color filters CF may be respectively provided in openings defined by the grid pattern 320. The microlenses ML may be disposed on the color filters CF.

According to one or more embodiments, the color filters CF may be respectively disposed on the pixel areas PXR. Alternatively, each of the color filters CF may be disposed on the plurality of pixel areas PXR (e.g., four pixel areas arranged in a 2×2 matrix form). Each of the color filters CF may have one color of red, green, and blue colors. Alternatively, each of the color filters CF may have one color of cyan, magenta, and yellow colors.

The grid pattern 320 may be disposed between adjacent two color filters CF. The color filters CF may be physically and optically separated from each other by the grid pattern 320. Therefore, the grid pattern 320 may guide incident light into the photoelectric conversion area 120.

The grid pattern 320 may include a metal and/or a low refractive material. The low refractive material may include a polymer and silica nanoparticles in the polymer. The low refractive material may have an insulating property. As another example, the grid pattern 320 may include a metal and/or a metal nitride. For example, the grid pattern 320 may include titanium and/or a titanium nitride.

In one or more embodiments, the grid pattern 320 may vertically overlap the deep trench isolator 130. However, the present disclosure is not limited thereto. In one or more embodiments, the grid pattern 320 may have a structure laterally offset from the deep trench isolator 130. The offset structure may be intentionally selected to optimize a light path in consideration of a margin of a manufacturing process and/or a proceeding angle of the incident light.

At least a portion of each of the microlenses ML may be disposed to vertically overlap the corresponding photoelectric conversion areas 120. Each of the microlenses ML may be provided to concentrate the incident light and may include a spherical lens, an aspherical lens, or a combination thereof. In one or more embodiments, the microlenses ML may be provided at locations corresponding to the photoelectric conversion areas 120 of the substrate 110, respectively. However, the embodiments of the present disclosure are not limited thereto. In one or more embodiments, the microlens ML may have a structure laterally offset from a location corresponding to the pixel area PXR. The offset structure may be intentionally selected to optimize a light path in consideration of a margin of a manufacturing process of the microlens ML and/or a proceeding angle of the incident light, etc. In this case, the above-described grid pattern 320, the color filters CF, and the microlenses ML may have the offset structure.

The microlens ML may be transparent and may transmit light. The microlens ML may include an organic material such as polymer. For example, the microlens ML may include a photoresist material or a thermosetting resin.

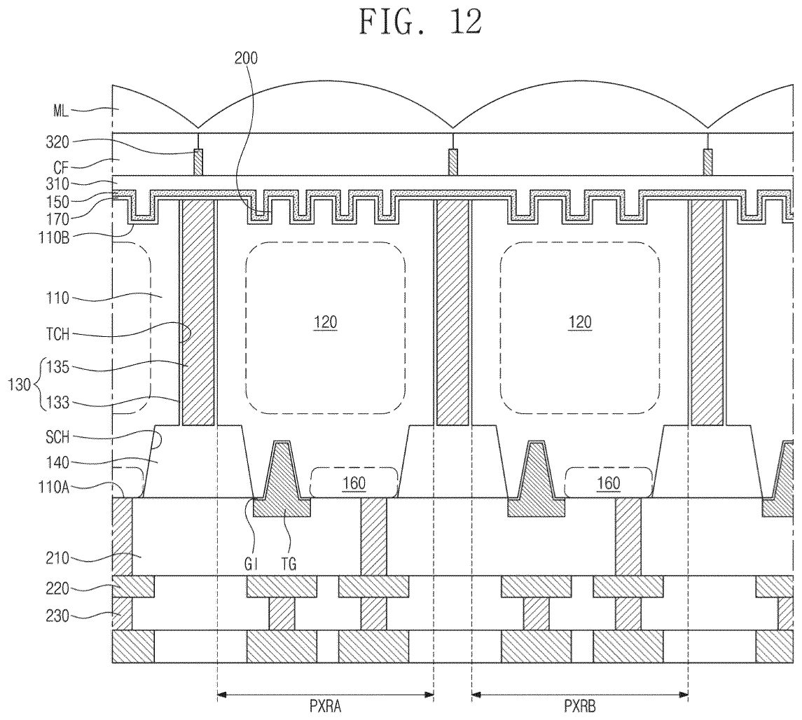

FIG. 12 is a cross-sectional view showing the light detection sensor according to one or more embodiments of the present disclosure. Hereinafter, for convenience of explanation, differences between the present embodiment and the embodiment in FIG. 12 will mainly be described.

Referring to FIG. 12, the plurality of recesses 200 may be provided in each of the pixel areas PXRA and PXRB. The recesses 200 in each of the pixel areas PXRA and PXRB may be arranged in one direction or two directions parallel to the second surface 110b of the substrate 110.

In one or more embodiments, sizes and/or intervals of the recesses 200 in each of the pixel areas PXRa and PXRb may be adjusted according to a wavelength of light incident on each of the pixel areas PXRa and PXRb. In one or more embodiments, sizes and/or intervals of the recesses 200 in one PXRa of the pixel areas in a first direction may differ from sizes and/or intervals of the recesses 200 in other one PXRb of the pixel area in the first direction. In this case, the first direction may be parallel to the second surface 100b. Also, a color of a color filter CF corresponding to the one pixel area PXRa may differ from a color of a color filter CF corresponding to the other one pixel area PXRb.

A wavelength of the light incident on the one pixel area PXRa may differ from a wavelength of the light incident on the other one pixel area PXRb. Accordingly, as described above, the sizes and/or the intervals of the recesses 200 in the one pixel area PXRa may be adjusted to improve light receptivity of the light incident on the one pixel area PXRa, and the sizes and/or intervals of the recesses 200 in the other one pixel area PXRb may be adjusted to improve the light receptivity of the light incident on the other one pixel area PXRb. As a result, light efficiency of both the one pixel area PXRa and the other one pixel area PXRb may be improved.

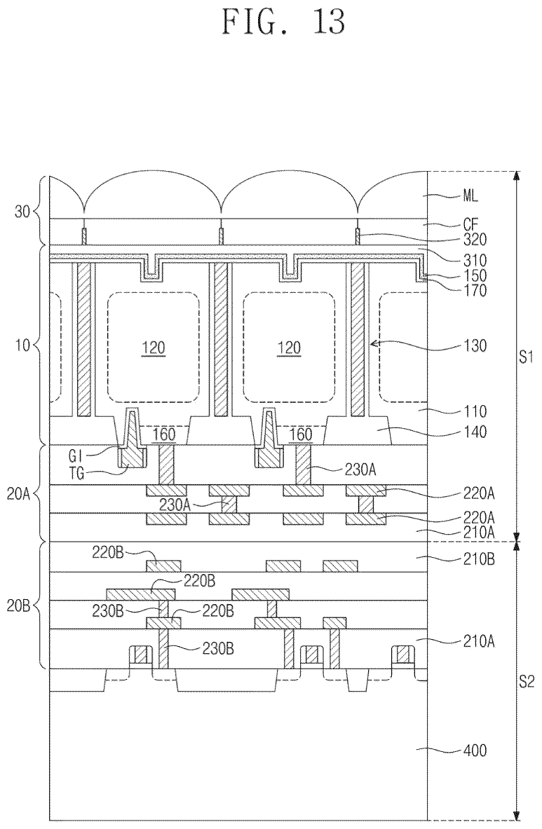

FIG. 13 is a cross-sectional view showing a light detection sensor according to one or more embodiments of the present disclosure.

Referring to FIG. 13, the light detection sensor may include a first structure S1 and a second structure S2. The first structure S1 may be disposed on the second structure S2. The first structure S1 may include a light transmission layer 30, a photoelectric conversion layer 10, and a first circuit wiring layer 20a. The photoelectric conversion layer 10 may be disposed between the light transmission layer 30 and the first circuit wiring layer 20a.

The light transmission layer 30 may include the microlenses ML, the color filters CF, the grid pattern 320, and the second insulating film 310 of FIG. 11 or FIG. 12. The photoelectric conversion layer 10 may include the transparent electrode 150, the first insulating film 170, the photoelectric conversion area 120, the substrate 110 (hereinafter, referred to as the first substrate), the deep trench isolator 130, the shallow trench isolator 140, the gate dielectric film GI, the transfer gates TG, the floating diffusion regions 160, and the gates and source/drain areas of the logic transistors (RX, SX, and DX of FIG. 10) of FIG. 11 or FIG. 12. The first circuit wiring layer 20a may include first interlayer insulating films 210a, first wirings 220a, and first contact plugs 230a. The first interlayer insulating films 210a, the first wirings 220a, and the first contact plugs 230a may correspond to the interlayer insulating films 210, the wirings 220, and the contact plugs 230 of FIG. 11 or FIG. 12.

The second structure S2 may include a second substrate 400 and a second circuit wiring layer 20b on the second substrate 400. Peripheral circuit transistors may be formed on the second substrate 400. The second circuit wiring layer 20b may include second interlayer insulating films 210b, second wirings 220b, and second contact plugs 230b covering the peripheral circuit transistors. The second wirings 220b and the second contact plugs 230b may be provided in the second interlayer insulating films 210b and electrically connected to the peripheral circuit transistors.

The second structure S2 may include various peripheral circuits to operate the pixels in the first structure S1. That is, the second wirings 220b, the second contact plugs 230b, and the peripheral circuit transistors may configure various peripheral circuits.

The second circuit wiring layer 20b may be disposed between the first circuit wiring layer 20a and the second substrate 400. The lowermost of the first interlayer insulating films 210a may be bonded to the uppermost of the second interlayer insulating films 210b. The first structure S1 may be electrically connected to the second structure S2 through through-electrodes in an edge area of the first structure S1. Alternatively, a first bonding pad may be disposed in the lowermost first interlayer insulating film 210a, a second bonding pad may be disposed in the uppermost second interlayer insulating film 210b, and the first bonding pad may be bonded to the second bonding pad. In this case, the first structure S1 may be electrically connected to the second structure S2 through the first and second bonding pads. The first and second bonding pads may include copper.

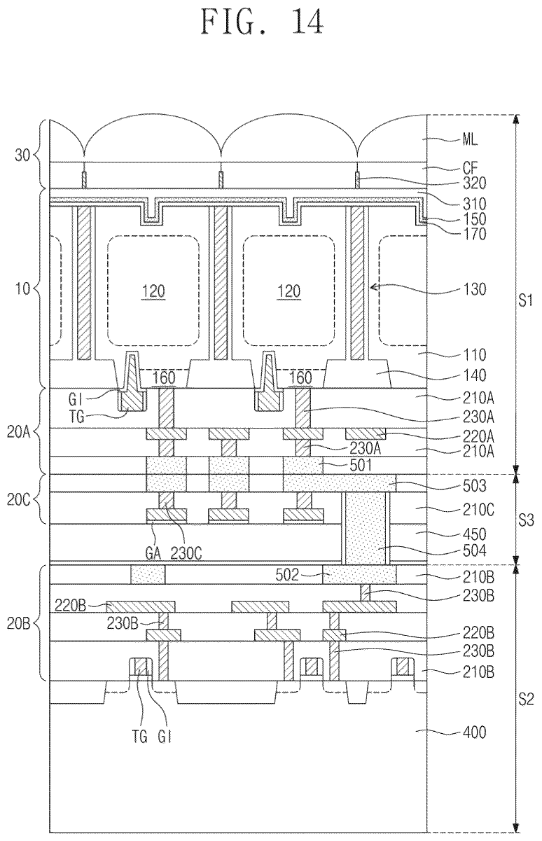

FIG. 14 is a cross-sectional view showing the light detection sensor according to one or more embodiments of the present disclosure.

Referring to FIG. 14, the light detection sensor may include the first structure S1, the second structure S2, and a third structure S3. The third structure S3 may be disposed between the first structure S1 and the second structure S2.

The first structure S1 may include the light transmission layer 30, the photoelectric conversion layer 10, and the first circuit wiring layer 20a. The light transmission layer 30 may be the same as the light transmission layer of FIG. 13. The photoelectric conversion layer 10 may include the transparent electrode 150, the first insulating film 170, the photoelectric conversion areas 120, the first substrate 110, the deep trench isolator 130, the shallow trench isolator 140, the gate dielectric film GI, the transfer gates TG, and the floating diffusion regions 160. The first circuit wiring layer 20a may include the first interlayer insulating films 210a, the first wirings 220a, the first contact plugs 230a, and first bonding pads 501.

The second structure S2 may include the second substrate 400 and the second circuit wiring layer 20b on the second substrate 400. The second structure S2 may be substantially the same as the second structure S2 of FIG. 13. However, the second structure S2 may further include second bonding pads 502 provided in the uppermost of the second interlayer insulating films 210b.

The third structure S3 may include a third substrate 450, gates GA on the third substrate 450, and a third circuit wiring layer 20c provided on the third substrate 450. The third substrate 450 may be a semiconductor substrate. Each of the gates GA may be disposed on the third substrate 450 with a gate dielectric film interposed therebetween. Source/drain areas may be provided on both sides of each of the gates GA in the third substrate 450.

The third circuit wiring layer 20c may include third interlayer insulating films 210c, third contact plugs 230c, third bonding pads 503, and at least one fourth bonding pad 504. The third circuit wiring layer 20c may further include third wirings, and each of the third wirings may be electrically connected to a corresponding gate GA, a corresponding source/drain area, the third bonding pad 503, and/or the fourth bonding pad 504.

According to the present embodiment, the first structure S1 may include some components of the pixel PXL of FIG. 10 and the third structure S3 may include other components of the pixel PXL of FIG. 10. For example, the first structure S1 may include the photoelectric conversion element PD, the transfer transistor TX, and the floating diffusion region FD of the pixel PXL, and the third structure S3 may include the logic transistors RX, SX, and DX of the pixel PXL.

In one or more embodiments, the first structure S1 and the third structure S3 may be bonded to each other by a copper-to-copper bonding method, and the third structure S3 and the second structure S2 may also be bonded to each other by the copper-to-copper bonding method. For example, the bonding pads 501, 502, 503, and 504 of the first, second, and third structures S1, S2, and S3 may be formed of copper. The first bonding pad 501 of the first structure S1 may be bonded to the third bonding pad 503 of the third structure S3, and the second bonding pad 502 of the second structure S2 may be bonded to the fourth bonding pad 504 of the third structure S3. In one or more embodiments, the fourth bonding pad 504 may pass through the third substrate 450 to be bonded to the second bonding pad 502.

According to embodiments of the present disclosure, at least one recess may be recessed into the pixel area from the second surface of the substrate, and the transparent electrode may cover the second surface of the substrate and the inner surface of the recess. Light loss can be minimized by the recess and the transparent electrode. In addition, when the light detection sensor operates, a negative bias voltage may be applied to the transparent electrode, thereby minimizing or preventing dark current.

Although the present disclosure has been described above with reference to one or more embodiments, it will be understood that those skilled in the art or those having ordinary knowledge in the art can modify and change the present disclosure in various ways within the scope of the disclosure without departing from the spirit and technical area of the present disclosure as set forth in the claims described below. Therefore, the technical scope of the present disclosure should not be limited to what is described in the detailed description of the specification but should be determined by the claims.

What is claimed is:

1. A light detection sensor comprising:
a substrate comprising a first surface and a second surface opposite to the first surface, wherein the second surface is a light incident surface;
a deep trench isolator within a deep trench in the substrate and defining a pixel area;
at least one recess into the pixel area from the second surface;
a transparent electrode on the second surface and an inner surface of the at least one recess; and
a first insulating film between the transparent electrode and the second surface and between the transparent electrode and the inner surface of the at least one recess.

2. The light detection sensor of claim 1, wherein the transparent electrode is configured to receive a negative bias voltage.

3. The light detection sensor of claim 2, wherein a cross-section of the at least one recess comprises a rectangular shape.

4. The light detection sensor of claim 2, wherein a cross-section of the at least one recess comprises an inverted triangular shape.

5. The light detection sensor of claim 2, further comprising a plurality of recesses into the pixel area from the second surface, wherein the plurality of recesses includes the at least one recess, and wherein the plurality of recesses are arranged in one direction or two directions parallel to the second surface of the substrate.

6. The light detection sensor of claim 2, wherein a width of a lower part of the at least one recess in a first direction parallel to the second surface is greater than a width of an upper part of the at least one recess in the first direction.

7. The light detection sensor of claim 2, wherein the transparent electrode comprises a transparent conductive oxide, and
wherein the transparent conductive oxide comprises at least one of indium tin oxide (ITO), indium zinc oxide (IZO), indium gallium zinc oxide (IGZO), titanium oxide (TiO2), aluminum-doped zinc oxide (ZnO:Al; AZO), fluorine-doped tin oxide, and niobium-doped anatase.

8. The light detection sensor of claim 2, wherein the first insulating film comprises a transparent insulating material.

9. The light detection sensor of claim 2, wherein the deep trench isolator comprises:
a buried conductive pattern within the deep trench; and
an insulating liner between the buried conductive pattern and the substrate, and
wherein the transparent electrode passes through the first insulating film and is connected to the buried conductive pattern,
wherein a first end of the buried conductive pattern is uneven, and
wherein the first end faces the first surface of the substrate.

10. The light detection sensor of claim 2,
wherein the transparent electrode and the first insulating film extend onto an inner surface of the deep trench, and
wherein the transparent electrode and the first insulating film within the deep trench are included in the deep trench isolator.

11. The light detection sensor of claim 2, further comprising:
a second insulating film on the transparent electrode,
wherein the second insulating film fills a remaining inner area of the at least one recess.

12. The light detection sensor of claim 2, further comprising:
a transfer gate on the first surface,
wherein the transfer gate extends into the substrate, and
wherein the deep trench is in contact with the first surface and the second surface.

13. A light detection sensor comprising:
a substrate comprising a first surface and a second surface opposite to the first surface, wherein the second surface is a light incident surface;
a deep trench isolator within a deep trench in the substrate and defining a plurality of pixel areas;
at least one recess in each of the plurality of pixel areas from the second surface;
a transparent electrode on the second surface and inner surfaces of each of the at least one recess in each of the plurality of pixel areas;
a first insulating film between the transparent electrode and the second surface and between the transparent electrode and the inner surfaces of each of the at least one recess in each of the plurality of pixel areas; and
a second insulating film on each transparent electrode.

14. The light detection sensor of claim 13, wherein the transparent electrode is configured to receive a negative bias voltage.

15. The light detection sensor of claim 14, wherein a cross-section of each of the at least one recess comprises a rectangular shape or an inverted triangular shape.

16. The light detection sensor of claim 14, wherein a width of a lower part of each of the at least one recess in each of the plurality of pixel areas is greater than a width of an upper part of each of the at least one recess in each of the plurality of pixel areas.

17. The light detection sensor of claim 14, further comprising:
a plurality of transfer gates on the first surface, wherein each of the plurality of transfer gates extends into the substrate.

18. The light detection sensor of claim 17, further comprising a plurality of recesses in each of the plurality of pixel areas,
wherein a size or an interval of the plurality of recesses in a first pixel area of the plurality of pixel areas in a first direction are different from a size or an interval of the plurality of recesses in a second pixel area of the plurality of pixel areas in the first direction,
wherein a color of the color filter corresponding to the first pixel area is different from a color of the color filter corresponding to the second pixel area, and
wherein the first direction is parallel to the second surface.

19. The light detection sensor of claim 13, wherein the deep trench isolator comprises:
a buried conductive pattern within the deep trench; and
an insulating liner between the buried conductive pattern and the substrate, and
wherein the transparent electrode passes through the first insulating film and is connected to the buried conductive pattern.

20. The light detection sensor of claim 13, wherein the transparent electrode and the first insulating film extend onto an inner surface of the deep trench, and
wherein the transparent electrode and the first insulating film within the deep trench are included in the deep trench isolator.
